(19) United States
(12) Patent Application Publication
(10) Pub. No.: US 2016/0050773 A1
(43) Pub. Date: Feb. 18, 2016

(54) OUTPUT MODULE FOR VEHICLE GAUGES

(71) Applicant: ISSPRO, Inc., Portland, OR (US)

(72) Inventors: William R. Larson, Vancouver, WA (US); Rocky A. Brown, Clatskanie, OR (US); Christopher J. Brown, Oregon City, OR (US); Michael J. Pliska, Happy Valley, OR (US); Kenneth B. Hangartner, Estacada, OR (US)

(21) Appl. No.: 14/461,611

(22) Filed: Aug. 18, 2014

(51) Int. Cl. H05K 5/00; B60K 35/00; B60R 16/023

(52) U.S. Cl. CPC H05K 5/0073; B60R 16/0232; B60K 35/00; B60K 2350/1056; B60K 2350/92

(57) ABSTRACT

Presently disclosed output modules may be removably and directly connected to a vehicle gauge. For example, the output module may be directly mounted on or plugged into the back of the gauge, such as by using the existing mounting bosses of the gauge. Disclosed output modules may be used with existing micro-processor-controlled gauges to send a desired switch signal to an external device, such as a warning light or a kill switch, when measured data hits a trigger point. Prior to attachment of the output module, the end-user may program the gauge via connection to a computer or other device, in order to set the desired trigger point or threshold value. Once the gauge is programmed with the desired trigger point, the output module may be attached to the back side of the gauge and may be wired to the external device to be controlled.

### FIELD

The present disclosure relates to output modules for vehicle gauges and methods of controlling an external device via an output module.

### BACKGROUND

Vehicle gauges typically include electronic instrumentation, sensors, and/or controls for monitoring an engine and/or one or more vehicle systems or parameters and for displaying information regarding current conditions of the monitored system or parameter. Vehicle gauges may be connected to a sensor to monitor operating conditions of the vehicle and display information regarding such operating conditions. For example, a fuel level gauge may be coupled to a fuel level sensor, the gauge being configured to display information regarding the current fuel level of the vehicle. Vehicle gauges are typically mounted in the dashboard or instrument panel of a vehicle, and positioned for reference by a driver or operator.

After-market vehicle gauges are available to customize instrument panels in a vehicle. In some instances, vehicle gauges may be programmable and may include hardware or other components to control an external device, such as a speaker, a light, or the vehicle's engine. For example, a programmable vehicle gauge may be configured to produce a sound (e.g., a beep or alarm) or turn on a warning light in response to sensing a condition that is above or below a threshold condition. Or a programmable vehicle gauge may function as a kill switch and be configured to shut off the engine if, for example, the oil pressure rises above a programmed threshold level. The threshold level may be variable by programming the gauge. For example, in the case of a programmable fuel level gauge, the gauge may be programmed to control a speaker to produce a sound once the fuel level sensor detects a fuel level that is below a programmed threshold value. Such programmable gauges with built-in hardware for controlling an external device are typically costly to manufacture, and therefore expensive for consumers. Further, not all consumers require or desire the functionality of controlling an external device via the gauge. There thus remains a need for an improved solution for a programmable vehicle gauge that can optionally control an external device.

### SUMMARY

According to the present disclosure, a vehicle gauge may include a removable output module that is directly mounted on or plugged into the gauge. In some examples, the existing mounting bosses of the gauge may be utilized for securing the output module to the gauge. For example, elastomeric grommets extending through holes in a circuit board of the output module may be configured to friction fit with the existing mounting bosses on the rear of the gauge's housing in order to secure the output module to the vehicle gauge. In some examples, disclosed output modules may have a thin profile, permitting them to be installed in the typically tight locations where gauges are installed.

In this manner, the output module may be structurally designed to be mounted directly to an existing gauge without requiring structural modification to the gauge and while permitting the gauge's existing mounting structure to continue being used. In some examples, existing programming pin connections on the vehicle gauge may be utilized for communication between the output module and the vehicle gauge.

The output module may be configured to control at least one aspect of an external device's functionality based on switch signals received from the gauge. For example, disclosed output modules may be used with existing micro-processor-controlled gauges to send a desired switch signal to an external device, such as a warning light or a kill switch, when the measured data hits a trigger point. The switch signal may be associated with the measured data of the gauge to which it is selectively connected and may be configured to, for example, turn on or turn off the external device. In one specific example, when a pre-programmed threshold oil pressure (e.g., measured data) is detected by the gauge, the gauge may send a signal to the output module via the programming pins, and the output module may send a switch signal to enable an external device such as an engine kill switch, thereby automatically shutting off the vehicle's engine in response to the oil pressure exceeding the programmed maximum threshold value.

Generally, disclosed output modules may include a relay and passive circuit devices mounted on a circuit board. Prior to attachment of the output module, the end-user may program the gauge via connection to a computer or other device, in order to set the desired trigger point or threshold value. Once the gauge is programmed with the desired trigger point, the output module may be attached to the back side of the gauge and may be wired to the external device that is to be controlled.

The vehicle gauge and output module may be sold together in some examples, or the output module may be sold separately from the vehicle gauge. The vehicle gauge may be an aftermarket gauge. Selling a separate output module as disclosed may allow for the selling of a standard (off-the-shelf) line of programmable gauges at a lower price point than if the output module's hardware and functionality were built into the off-the-shelf gauges. Moreover, the programmable gauges may be sold with the requisite software pre-installed. Thus, customers that do not desire the functionality of the output module do not need to incur the expense for such functionality, while customers that do desire such functionality may separately purchase the output module and install it in connection with the off-the-shelf gauges.

### BRIEF DESCRIPTION OF THE DRAWINGS

FIG. 1 is a schematic representation of illustrative, non-exclusive examples of a vehicle gauge, output module, and external device according to the present disclosure.

FIG. 2 is a perspective view of an illustrative, non-exclusive example of a vehicle gauge, viewed from the front, left side of the vehicle gauge.

FIG. 3 is a perspective view of the back side of the vehicle gauge of FIG. 2.

FIG. 4 is a top plan view of an illustrative, non-exclusive example of an output module according to the present disclosure.

FIG. 5 is a side elevation view of an illustrative, non-exclusive example of an output module according to the present disclosure.

FIG. 6 is a perspective view of an illustrative, non-exclusive example of an output module partially connected to a vehicle gauge according to the present disclosure.

FIG. 7 is a plan view of an illustrative, non-exclusive example of an output module coupled to a vehicle gauge according to the present disclosure.

FIG. 8 is a perspective view of the output module and vehicle gauge of FIG. 7, showing wiring connections for an external device.

FIG. 9 is a schematic diagram view of an illustrative, non-exclusive example of an output module circuit according to the present disclosure.

FIG. 10 is a schematic block diagram of illustrative, non-exclusive examples of methods of selling an output module separate from a vehicle gauge according to the present disclosure.

FIG. 11 is a schematic block diagram of illustrative, non-exclusive examples of methods of using an output module according to the present disclosure.

### DETAILED DESCRIPTION

According to the present disclosure, a vehicle gauge 100 (also referred to herein as gauge 100) may include a removable output module 102 that is directly mounted on, connected to, plugged into, and/or otherwise secured to gauge 100 via a direct mounting connection 104. Output module 102 may be configured to control an external device 106 based on switch signals received from gauge 100. Vehicle gauge 100 may be programmable, such as via a programming connection 108. Additionally or alternatively, vehicle gauge 100 may be micro-processor controlled. According to disclosed embodiments, vehicle gauges 100 may be combined with separate output modules 102 in order to control external device 106, without requiring circuitry for controlling external devices to be present on the gauge 100 itself. This arrangement may reduce manufacturing costs of vehicle gauge 100, and thereby provide an option for a programmable gauge without such functionality for those users who do not desire such functionality, while offering the capability of controlling an external device by coupling a disclosed output module 102 to vehicle gauge 100.

Vehicle gauge 100 may include a housing 110 having a display face 112 (also referred to herein as a display opening 112, typically formed as an opening in housing 110 with a piece of clear plastic or glass covering the display face 112) and a rear face 114. Vehicle gauge 100 may be any type of vehicle gauge, and may be configured to display parameters concerning vehicle performance or vehicle systems (e.g., information detected or sensed by a sensor within or connected to gauge 100). For example, vehicle gauge 100 may be a gauge configured to display information related to the performance of a vehicle system. In some examples, vehicle gauge 100 may be a tachometer, a speedometer, a temperature gauge (such as an oil temperature, coolant temperature, air intake temperature, external air temperature, fuel temperature, exhaust gas temperature, battery temperature, or transmission temperature gauge), an oil pressure gauge, a knock retard gauge, a battery level gauge (e.g., voltage detector), a pyrometer, a fuel economy gauge, a voltmeter, an ammeter, a boost gauge, an hourmeter, an air pressure gauge, a pressure sensor, a vacuum gauge, a fuel pressure gauge, a manifold pressure gauge, and/or a fuel level gauge. Gauge 100 may be a digital gauge configured to display system information digitally, or gauge 100 may be an analog gauge, typically including a needle or pointer 116 that moves back and forth along a continuum or range 118 (also referred to herein as scale 118) shown on the display face 112 in accordance with the present level of data (e.g., the present fuel level, or the present oil temperature) detected or determined.

Generally, vehicle gauge 100 is configured to be installed within or displayed within a vehicle 120 (e.g., a commercial or personal vehicle, such as a car, truck, van, golf cart, all-terrain vehicle, military vehicle, aircraft, boat, motorcycle, scooter, bus, train, RV, snowmobile, or any other type of vehicle) such that an operator of the vehicle can view the display face 112 during operation of the vehicle. Vehicle gauge 100 may be, for example, mounted on or in a dashboard or instrument panel of vehicle 120. Vehicle gauge 100 may be configured as a factory gauge installed within vehicle 120 at the time of manufacture, and/or vehicle gauge 100 may be configured as an aftermarket gauge, available for sale separate from vehicle 120 and able to be installed or mounted by a user.

Vehicle gauge 100 may include one or more mounting structures 122. Mounting structures 122 may be configured to mount vehicle gauge 100 within vehicle 120. In some examples, the direct mounting connection 104 that couples output module 102 to vehicle gauge 100 may function as a mounting structure 122 and also be functional to mount vehicle gauge 100 within vehicle 120. In some examples, mounting structures 122 may be separate from direct mounting connection 104. Any number of mounting structures 122 may be included on gauge 100, such as at least one, at least two, at least three, at least four, at least five, or six or more mounting structures 122. Mounting structures 122 may be positioned anywhere on vehicle gauge 100, such as on gauge housing 110, on display face 112, and/or on rear face 114. In one specific example, vehicle gauge 100 may include two bosses 124 that function as mounting structures 122 and as direct mounting connection 104. In this example, bosses 124 may extend from the rear face 114 of gauge 100, may be configured to mount gauge 100 within vehicle 120, and also may be configured to couple output module 102 with vehicle gauge 100.

In some examples, mounting structures 122 may be existing mounting bosses of gauge 100 such that output module 102 may be coupled to gauge 100 without any modification of gauge 100 (e.g., gauge 100 may be an off-the-shelf gauge). In some examples and as will be explained in further detail, elastomeric grommets extending through holes in a circuit board of the output module 102 may be configured to friction fit with the existing mounting bosses on the rear face 114 of the gauge's housing 110 in order to secure output module 102 to vehicle gauge 100. In some examples, disclosed output modules 102 may have a thin profile, permitting them to be installed in most tight locations where gauges 100 typically are installed. In this manner, output module 102 may be structurally designed to be mounted directly to an existing gauge 100 without requiring structural modification to gauge 100 and while permitting the gauge's existing mounting structure 122 to continue being used.

In some examples, an existing programming connection 108 on vehicle gauge 100 may be utilized for communication between output module 102 and vehicle gauge 100. Programming connection 108 may comprise a plurality of pins, a connector, a plug, a jack, a wireless receiver, and/or any structure suitable for providing at least a temporary electrical connection with a device (e.g., a computer, a programmer, a mobile device, etc.) configured to program vehicle gauge 100 according to a user's desired parameters. In some examples, programming connection 108 may also be configured to deliver signals to output module 102 (e.g., output module 102 may be electrically coupled to vehicle gauge 100 via at least a portion of programming connection 108 when output module 102 is attached to vehicle gauge 100).

Direct mounting connection 104 may be any suitable structure that may be configured to secure, connect, attach, couple, and/or mount output module 102 to vehicle gauge 100. For example, output module 102 may be connected directly to gauge 100 via direct mounting connection 104, which may be one or more plugs, snaps, fasteners, screws, adhesive, magnets, pins, or any other suitable connection. In some examples, direct mounting connection 104 may include hardware on both output module 102 and vehicle gauge 100 (e.g., direct mounting connection 104 may comprise complementary structures on vehicle gauge 100 and output module 102). In one specific example, direct mounting connection 104 may comprise mounting bosses on vehicle gauge 100 and corresponding holes formed in output module 102 that may be mounted on the mounting bosses on vehicle gauge 100. Such direct mounting connections 104 may provide for a friction fit attachment between output module 102 and vehicle gauge 100. In some examples, direct mounting connection 104 may be configured to permanently attach output module 102 to vehicle gauge 100. In some examples, direct mounting connection 104 may be configured to removably attach output module 102 to vehicle gauge 100 such that output module 102 may be secured to vehicle gauge 100 and subsequently removed from vehicle gauge 100 without damage to vehicle gauge 100 or output module 102.

External device 106 may be any external device that is separate from vehicle gauge 100. For example, external device 106 may be one or more of a warning light, a kill switch, a buzzer, a speaker, an alarm, a blinking light, a fan (e.g., an electric cooling fan), a water injection kit, an alcohol injection kit, a nitrous kit, and/or any other external device desired to be controlled in response to detected events or vehicle conditions. External device 106 may be electrically coupled to output module 102 via an external device connection 126. External device connection 126 may be, for example, a wire or wires, a cable or cables, a solder joint or joints, a terminal or terminals, a plug or plugs, a socket or sockets, a connector or connectors, a receiver or receivers, a transmitter or transmitters, and/or a wireless connection. External device connection 126 may be any connection that permits output module 102 to send a switch signal to external device 106, thereby controlling at least one aspect or function of external device 106 in response to a condition detected by vehicle gauge 100. For example, a switch signal from output module 102 may turn external device 106 on, turn external device 106 off, enable external device 106, disable external device 106, increase performance of external device 106 (e.g., make external device 106 louder and/or brighter), decrease performance of external device 106 (e.g., make external device 106 quieter and/or dimmer), change the color of external device 106, change the frequency of external device 106, may prevent current and/or voltage from reaching external device 106, and/or may enable current and/or voltage to reach external device 106.

A switch signal may be transmitted to external device 106 upon a certain condition detected or determined by vehicle gauge 100. For example, when a measured level surpasses or falls below a programmed threshold level, or trigger point, vehicle gauge 100 may send a signal to output module 102, which in turn may be configured to send a switch signal to control performance of external device 106. Thereby, the switch signal may be associated with the measured data of the gauge to which it is selectively connected. The trigger point or threshold level in a given application may be variable and may be pre-programmed onto vehicle gauge 100. In one specific example, when a pre-programmed threshold oil pressure (e.g., measured data or a present vehicle condition) is detected or received by gauge 100, the gauge may send a signal to output module 102 via programming connection 108, and output module 102 may send a switch signal to external device 106 such as an engine kill switch. For example, vehicle gauge 100 may be programmed to set a maximum threshold oil pressure. In this example, if the current oil pressure (e.g., the measured, detected, received, or determined oil pressure) exceeds the set maximum threshold oil pressure (as programmed onto gauge 100), vehicle gauge 100 may send a signal to output module 102, which in turn may produce a switch signal (e.g., by opening or closing a circuit via a relay on the output module) to turn on or enable an external device such as an engine kill switch. In this example, the system may prevent the vehicle's engine from running at too high an oil pressure, as the gauge may be configurable to automatically shut down the vehicle's engine once the oil pressure exceeds the programmed maximum threshold value.

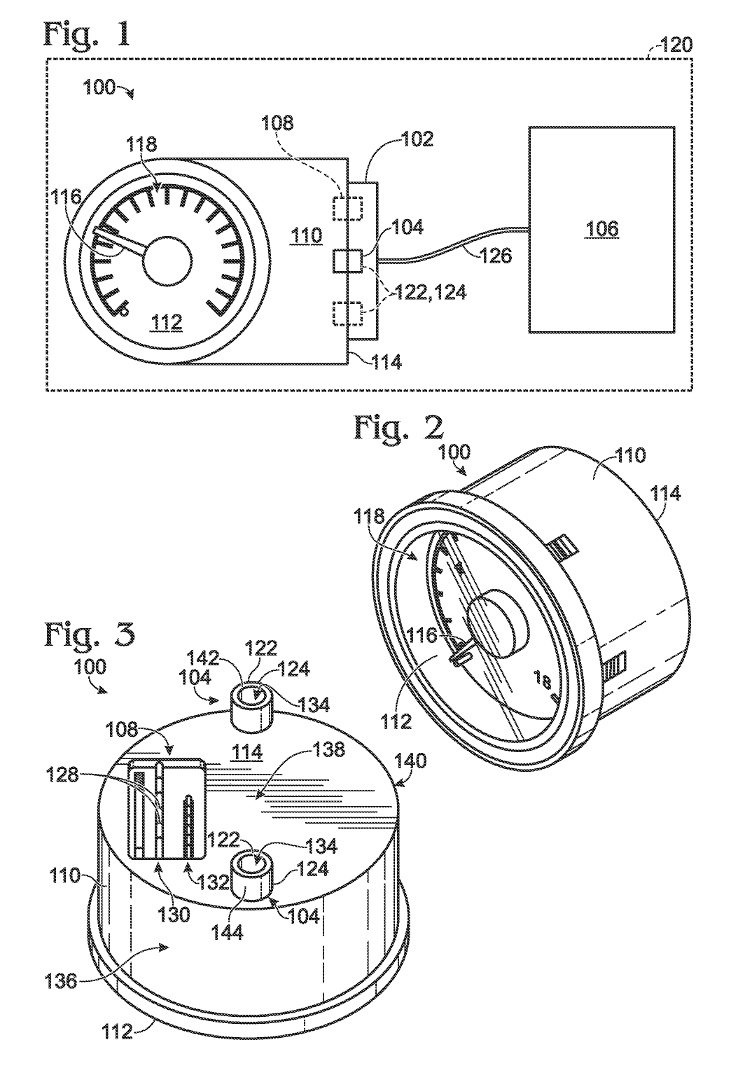

Turning now to FIGS. 2-9, illustrative non-exclusive examples of vehicle gauges and output modules according to the present disclosure are illustrated. Where appropriate, the reference numerals from the schematic illustrations of FIG. 1 are used to designate corresponding parts of disclosed vehicle gauges and output modules, however, the examples of FIGS. 2-9 are non-exclusive and do not limit the disclosed output modules and gauges to the illustrated embodiments of FIGS. 2-9. That is, disclosed vehicle gauges and output modules are not limited to the specific embodiments of FIGS. 2-9 and may incorporate any number of the various aspects, configurations, characteristics, properties, etc. that are illustrated in and discussed with reference to the schematic representations of FIG. 1 and/or the embodiments of FIGS. 2-9, as well as variations thereof, without requiring the inclusion of all such aspects, configurations, characteristics, properties, etc. For the purpose of brevity, each previously discussed component, part, portion, aspect, region, etc. or variants thereof may not be discussed, illustrated, and/or labeled again with respect to FIGS. 2-9, however, it is within the scope of the present disclosure that the previously discussed features, variants, etc. may be utilized with each of these examples.

FIGS. 2 and 3 show a front perspective view of an example of a vehicle gauge 100 (FIG. 2) and a rear perspective view of vehicle gauge 100 (FIG. 3). Vehicle gauge 100 may include housing 110, display face 112, and rear face 114. Gauge 100 is shown as having a generally cylindrical housing 110 with a generally circular display face 112 and rear face 114, however, other shapes are also possible. As seen in FIG. 3, gauge 100 may include programming connection 108, which may be in the form of a plurality of programming pins 128. Programming pins 128 may be arranged linearly and may be configured to receive one or more connectors. In some examples, programming connection 108 may comprise a first set of pins 130 and a second set of pins 132, each of which may be arranged linearly to form rows of pins 130, 132. In some specific examples, first set of pins 130 may be configured to program gauge 100 and/or couple an input from a sensor to gauge 100 and may be referred to as programming pins 130, and second set of pins 132 may be configured for communication with output module 102 (e.g., output module 102 may include a connector configured to connect to programming connection 108, such as second set of pins 132) and may be referred to as control pins 132.

As best seen in FIG. 2, display face 112 may include needle 116 that may move (e.g., rotate or move linearly up and down) in response to changing conditions, such that needle 116 points to the area along continuum, or scale, 118 that corresponds to the current level or condition detected. In this manner, gauge 100 may convey information regarding the current condition or level of the vehicle aspect that the gauge is configured to relay information regarding. In the illustrated example, gauge 100 may be configured as, for example, a pyrometer, and needle 116 may move in an arc along scale 118 as measured temperature rises or falls.

As best seen in FIG. 3, rear face 114 of vehicle gauge 100 may include one or more mounting structures 122. In the specific example shown, vehicle gauge 100 includes two mounting structures 122 in the form of mounting bosses 124. Mounting structures 122 may also form all or part of a direct mounting connection 104 for coupling with an output module 102. Mounting structure 122 may be configured to mount vehicle gauge 100 within a vehicle. For example, mounting bosses 124 may contain internal threads 134 that may engage with a screw or other fastener in order to mount gauge 100 in place, and/or otherwise secure gauge 100 within a vehicle. Mounting structures may be positioned anywhere on gauge 100. Mounting structures 122 are shown as positioned on rear face 114, but additionally or alternatively may be positioned elsewhere on the gauge housing 110, such as on or adjacent the circumferential periphery 136 of housing 110. Furthermore, mounting structures 122 may be positioned or arranged anywhere on rear face 114. For example, mounting structures 122 may be positioned near the center 138 of rear face 114, may be positioned adjacent the outer perimeter 140 of rear face 114, and/or may be positioned anywhere in between. As shown in FIG. 3, a first mounting structure 142 and a second mounting structure 144 may each be positioned adjacent outer perimeter 140 of rear face 114, on opposite sides of rear face 114. Any other suitable arrangement is also possible.

While two mounting structures 122 are shown in FIG. 3, more or fewer mounting structures 122 may be included in other examples. For example, one mounting structure, two mounting structures, three mounting structures, four mounting structures, five mounting structures, or six or more mounting structures may be included for securing gauge 100 within a vehicle. Further, while the illustrated mounting structures 122 are configured as mounting bosses 124 having a hollow cylindrical shape extending out from rear face 114, other configurations and shapes are also possible. For example, mounting structures 122 may be solid, rather than hollow. Mounting structures 122 may be spherical, ovoid, elliptical, square, rectangular, polygonal, or any other shape. In some examples, gauge 100 may include a separate direct mounting connection 104 for securing an output module 102 to gauge 100. In some examples, mounting structures 122 may serve both as a way to mount gauge 100 within a vehicle as well as serving as a direct mounting connection 104 for securing output module 102 to gauge 100.

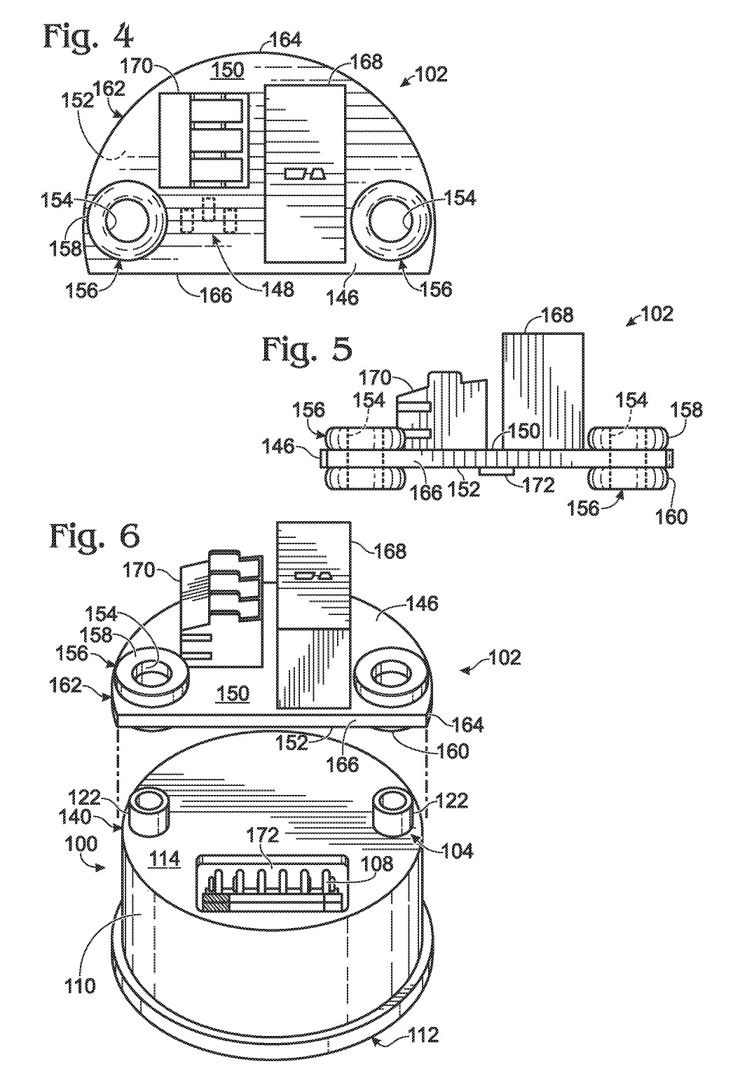

FIGS. 4 and 5 illustrate a schematic representation of a non-exclusive example of an output module 102, shown both from a top plan view (FIG. 4) as well as an elevation view (FIG. 5). Output module 102 may include a printed circuit board 146 having a plurality of passive circuit elements 148 thereon. Printed circuit board 146 may include an upper surface 150 and a lower surface 152, and one or more through-holes 154 (also referred to herein as mounting holes 154) extending through printed circuit board 146 from upper surface 150 to lower surface 152. Each through-hole 154 may include a grommet 156 (also referred to herein as mounting grommet 156) extending there-through. In some examples, grommet 156 may be an elastomeric grommet 156 configured with an upper flange 158 and a lower flange 160, where upper flange 158 may be positioned on or adjacent upper surface 150 and lower flange 160 may be positioned on or adjacent lower surface 152 of printed circuit board 146.

Printed circuit board 146 may have an outer perimeter 162 that may be any shape. In some examples, outer perimeter 162 is shaped to conform to a vehicle gauge 100, such as being conformed to rear face 114 of vehicle gauge 100. For example, outer perimeter 162 may be circular, oval, square, rectangular, polygonal, irregular, or any other shape. In some examples, outer perimeter 162 may include an arc portion 164 and a straight portion 166. Arc portion 164 may form at least a semi-circle in some examples and may be configured to be approximately the size and shape of a rear face of a vehicle gauge. Once output module 102 is installed on or coupled to gauge 100, output module 102 may be positioned and oriented such that it is substantially parallel to rear face 114 of vehicle gauge 100. In this manner, outer perimeter 162 may be positioned relative to rear face 114 such that outer perimeter 162 does not extend beyond the outer perimeter 140 of rear face 114.

Generally, disclosed output modules 102 may include a relay 168 or other type of switch, and any other desired circuit devices mounted on circuit board 146. Relay 168 may be configured to open or close a circuit based on a signal received from gauge 100, thereby controlling whether current is delivered to external device 106. Relay 168 may be electrically isolated from gauge 100.

Printed circuit board 146 of output module 102 may also include a terminal 170 (also referred to herein as a terminal strip 170) or other connector that may be configured to provide an electrical connection between external device 106 and output module 102. Terminal 170 may be, for example, a screw terminal configured to form an electrical connection by inserting one or more wires into terminal 170 and screwing pins or contacts down onto the wires to form an electrical connection. In other examples, terminal 170 may be any sort of connectors, pins, contacts, solder joints, and/or wireless connection that can electrically couple external device 106 to output module 102.

Output module 102 may also include a connector 172 for establishing an electrical connection with vehicle gauge 100. For example, connector 172 may be positioned on lower surface 152 of printed circuit board 146 and may be configured to engage with programming connection 108 of vehicle gauge 100. In some examples, connector 172 may be plugged onto a first portion of programming connection 108 in a manner that allows simultaneous connection of a second portion of programming connection 108 to another device or sensor or input. In one specific example, connector 172 of output module 102 may be plugged onto second row of pins 132 of programming connection 108, leaving first row of pins 130 of programming connection 108 exposed. In this manner, vehicle gauge 100 may be electrically coupled to a sensor or other input via first row of pins 130 and also have an output module 102 coupled to it via second row of pins 132.

Prior to and/or after attachment of the output module 102 to a vehicle gauge 100, an end-user may program gauge 100 via connection to a computer or other device (e.g., via programming connection 108), in order to set a desired trigger point or threshold value. In some examples, once gauge 100 is programmed with the desired trigger point, output module 102 may be attached to, for example, rear face 114 of gauge 100 and may be wired to (or otherwise electrically coupled to) the external device 106 that is to be controlled. FIG. 6 illustrates a perspective view of an output module 102 in the process of being plugged into or coupled with vehicle gauge 100.

As shown in FIG. 6, output module 102 may be directly physically connected to, mounted on, plugged into, snapped onto, or otherwise directly coupled to vehicle gauge 100. In some examples, output module 102 is directly connected to rear face 114 of vehicle gauge 100. Through-holes 154 formed in printed circuit board 146 of output module 102 may be pressed onto a direct mounting connection 104, such as by being pressed onto one or more mounting structures 122. Mounting structures 122 may be, for example, mounting bosses formed on rear face 114 of output module 102. In some examples, mounting structures 122 may be configured to mount vehicle gauge 100 in place within a vehicle, and output module 102 may be configured to be pressed onto mounting structures 122 as well, such as by pressing mounting structures 122 through through-holes 154 of output module 102. In some examples, elastomeric grommets 156 positioned within through-holes 154 may be configured to provide a friction fit around mounting structures 122. In this manner, output module 102 may be selectively removable from vehicle gauge 100.

Additionally or alternatively to connecting via mounting structures 122, output module 102 may be mounted to vehicle gauge 100 via programming connection 108. Programming connection 108 may be configured to provide an electrical connection and/or a physical connection between output module 102 and vehicle gauge 100. For example, connector 172 of output module 102 may be inserted onto at least a portion of programming connection 108.

While FIG. 6 shows an example of an output module 102 with two through-holes 154 and a vehicle gauge 100 with two mounting structures 122, more or fewer of each are also possible. For example, in some examples, a vehicle gauge 100 may be provided with a single mounting structure 122 and output module 102 may be provided with a single corresponding structure configured to engage with mounting structure 122. In other examples, vehicle gauge 100 may have two or more, five or more, eight or more, or ten or more mounting structures 122, and output module 102 may include two or more, five or more, eight or more, or ten or more corresponding structures to engage with each respective mounting structure 122 on vehicle gauge 100. Additionally or alternatively, vehicle gauge 100 may have zero mounting structures 122, relying exclusively on programming connector 172 of output module 102 and programming connection 108 of vehicle gauge 100 to provide both the electrical and physical coupling of the output module 102 and vehicle gauge 100.

Additionally or alternatively, while FIG. 6 illustrates an output module 102 having through-holes 154 and grommets 156 for mounting to vehicle gauge 100, other mounting configurations are also possible. For example, output module 102 may include one or more snaps, magnets, fasteners, plugs, and/or connectors in addition to or instead of through-holes 154 and grommets 156 that may be configured for mounting output module 102 to vehicle gauge 100.

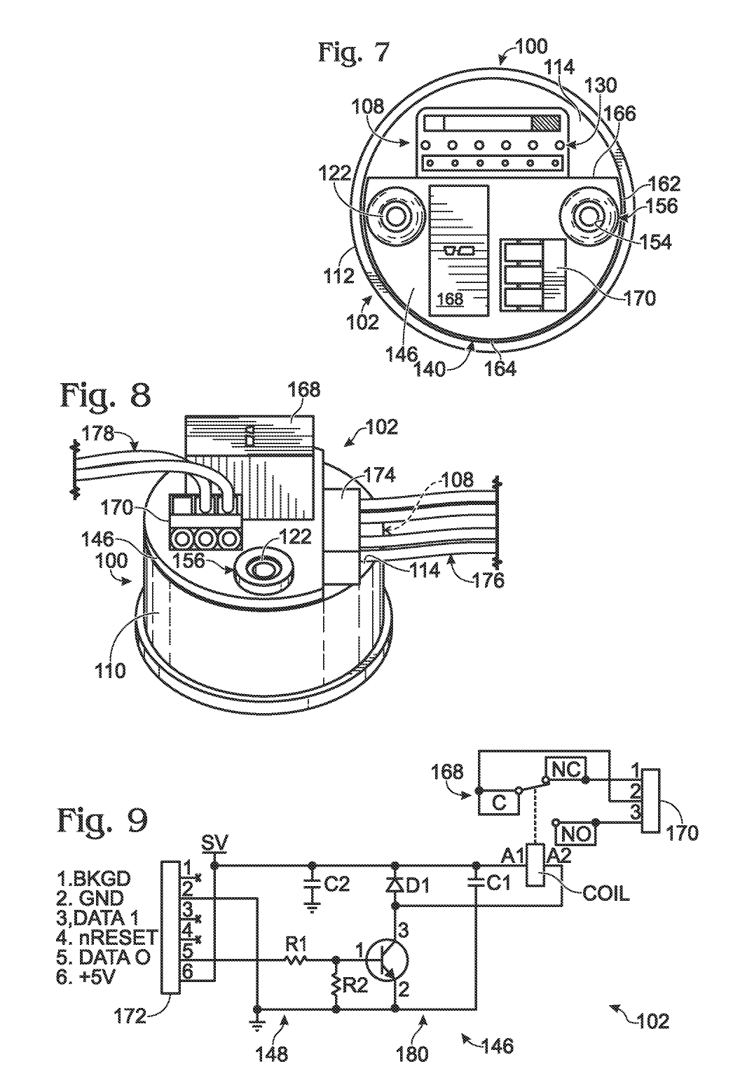

FIG. 7 illustrates an illustrative, non-exclusive example of an output module 102 fully mounted onto a vehicle gauge 100. As shown in FIG. 7, output module 102 may be directly mounted to vehicle gauge 100. Printed circuit board 146 of output module 102 may be very close to, or even touching, vehicle gauge 100 when output module 102 is fully mounted. In some examples, lower flanges 160 of elastomeric grommets 156 (See FIGS. 5-6) may contact rear face 114 of vehicle gauge 100 when output module 102 is fully pressed onto mounting structures 122. In some examples, the edges of mounting structures 122 may be essentially flush with the upper flanges 158 of grommets 156 when output module 102 is inserted in place on vehicle gauge 100.

As seen in FIG. 7, at least a portion of programming connection 108 of vehicle gauge 100 may be visible and/or accessible when output module 102 is connected to vehicle gauge 100. For example, first row of pins 130 may be visible and accessible while output module 102 is in place on vehicle gauge 100. In some examples, output module 102 may be positioned to cover or block a portion of programming connection 108 (e.g., output module 102 may include a connector (e.g., connector 172 of FIG. 6) that is plugged onto second row of pins 132 of programming connection 108).

In some examples, printed circuit board 146 of output module 102 may be sized and shaped to at least partially conform to vehicle gauge 100. For example, at least a portion of perimeter 162 of circuit board 146 may be approximately the same size and shape as perimeter 140 of rear face 114 of vehicle gauge 100. As seen in FIG. 7, arc portion 164 of circuit board 146 may be configured to have a radius of curvature that is approximately equal to that of perimeter 140 of rear face 114. In this manner, when output module 102 is mounted on vehicle gauge 100, the same may be configured such that output module 102 does not extend beyond outer perimeter 140 of rear face 114 of vehicle gauge 100.

Printed circuit board 146 of output module 102 may be configured to avoid interference with normal functioning of vehicle gauge 100. For example, while printed circuit board 146 may be mounted on mounting structures 122, output module 102 may be configured so as to not require modification of vehicle gauge 100, such that mounting structures 122 may still be used to mount vehicle gauge 100 within a vehicle even when output module 102 is secured to gauge 100. Further, printed circuit board 146 may be configured to allow access to aspects of vehicle gauge 100, such as by permitting access to at least a portion of programming connection 108 while output module 102 is secured to vehicle gauge 100. For example, as seen in FIG. 7, printed circuit board 146 may include an edge 166 that is configured to enable access to a portion of vehicle gauge 100. In some examples, edge 166 may be a straight edge 166 that is configured to allow access to at least a portion of programming connection 108 while output module 102 is mounted to vehicle gauge 100. In the example shown in FIG. 7, edge 166 of output module 102 may be configured so that at least first row of pins 130 of programming connection 108 is accessible while output module 102 is mounted on vehicle gauge 100.

Of course, other shapes for circuit board 146 are also possible. In some examples, perimeter 140 of circuit board 146 may be substantially entirely round, and may include cut-outs to allow access to portions of vehicle gauge 100. In some examples, perimeter 140 of circuit board 146 may be oval, irregularly shaped, square, rectangular, polygonal, and/or any other shape. Perimeter 140 of circuit board 146 may include straight edges and/or curved edges. While vehicle gauge 100 is illustrated as having a substantially cylindrical body and a circular rear face, other configurations are also possible, and disclosed embodiments are not limited to such.

FIG. 8 shows an illustrative, non-exclusive example of an output module 102 and vehicle gauge 100 having wiring connections for controlling an external device. As with other described examples, printed circuit board 146 of output module 102 may be mounted on mounting structures 122 of vehicle gauge 100. Elastomeric grommets 156 may be configured to provide a friction fit connection with mounting structures 122. Output module 102 may be configured so as to not interfere with installation of vehicle gauge 100 within a vehicle when output module 102 is mounted on gauge 100. For example, mounting structures 122 may be accessible for mounting vehicle gauge 100 within a vehicle even with output module 102 attached. Further, at least a portion of programming connection 108 may be accessible while output module 102 is secured to vehicle gauge 100. As shown in FIG. 8, while output module 102 is secured to vehicle gauge 100, an input connector 174 may also be connected to at least a portion of programming connection 108. In some specific examples, a connector 172 of output module 102 may be connected to a first portion of programming connection 108 (e.g., first row of pins 130) and input connector 174 may be connected to a second portion of programming connection 108 (e.g., second row of pins 132).

Input connector 174 may be configured to electrically couple vehicle gauge 100 to a sensor or other input, such as via one or more wires 176. Electrical signals may be received by vehicle gauge 100 via wires 176 and input connector 174 from vehicle systems such that vehicle gauge 100 is configured to display information concerning that system's current performance or parameters. For example, vehicle gauge 100 may be electrically coupled to a sensor (e.g., a temperature sensor) or other input via input connector 174 and input wires 176. In this manner, vehicle gauge 100 may receive information regarding vehicle performance or conditions, such as oil temperature, fuel level, engine RPMs, oil pressure, etc. Information regarding these inputs may be displayed to a user via gauge display face 112.

Terminal 170 may be configured to provide an electrical connection between output module 102 and an external device. For example, one or more output wires 178 may be coupled to terminal 170 and provided to electrically connect an external device such as a warning light, alarm, buzzer, and/or kill switch to output module 102. Via these connections, when an input exceeds or falls below a pre-programmed threshold value (e.g., when oil pressure exceeds a maximum threshold programmed into gauge 100), an external device may be activated or shut off. For example, a warning light (e.g., an external device) may be turned on via a switch signal sent via output wires 178 from output module 102 when a condition is detected.

Output module 102 may be encased in some embodiments, such as by being contained within a housing to protect elements positioned on circuit board 146. In some examples, output module 102 may be provided with wiring connections pre-installed. In other examples, wiring connections may be added by an end-user once output module 102 is installed on a gauge 100.

FIG. 9 shows a schematic diagram of one example of a circuit 180 that may be printed on and/or included on printed circuit board 146 of output module 102. Circuit 180 may include relay 168 and circuit elements 148. Terminal connector 170 may be electrically coupled to relay 168 and to an external device to be controlled by output module 102. Connector 172 may be electrically coupled to gauge 100 in order to receive information from gauge 100 regarding present vehicle conditions and parameters. FIG. 9 shows a specific non-exclusive illustrative example of a suitable circuit 180, but many other configurations are possible.

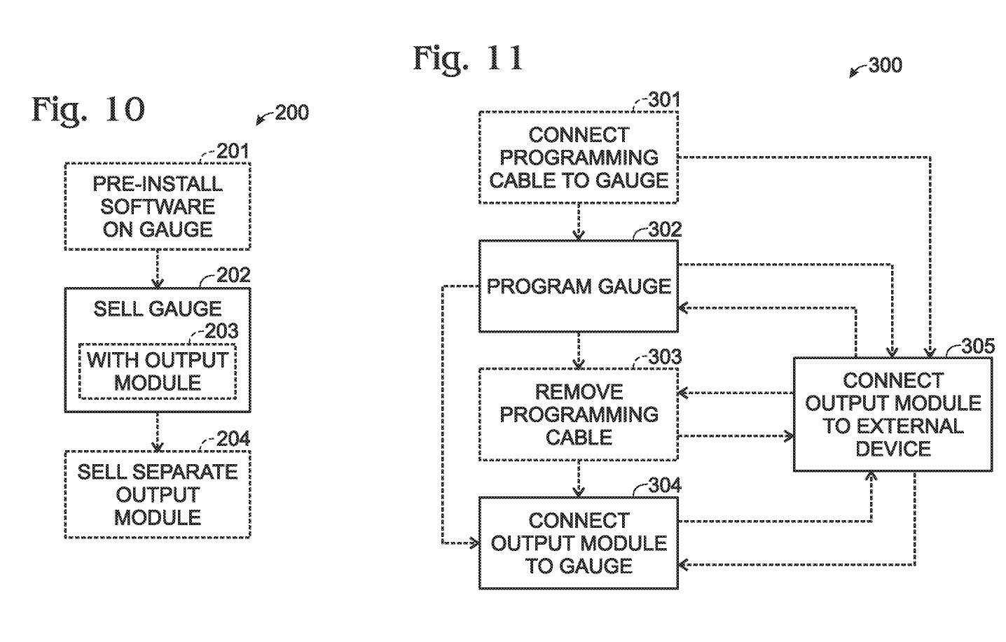

Turning now to FIGS. 10-11, schematic flowcharts are provided that represent illustrative, non-exclusive examples of methods according to the present disclosure. In FIGS. 10-11, some steps are illustrated in dashed boxes indicating that such steps may be optional or may correspond to an optional version of a method according to the present disclosure. That said, not all methods according to the present disclosure are required to include the steps illustrated in solid boxes. The methods and steps illustrated in FIGS. 10-11 are not limiting and other methods and steps are within the scope of the present disclosure, including methods having greater than or fewer than the number of steps illustrated, as understood from the discussions herein.

As shown in FIG. 10, a method 200 is provided for business methods of selling a programmable vehicle gauge 100 and output module 102 according to the present disclosure. In some examples, software may be pre-installed on a programmable vehicle gauge at 201. A programmable vehicle gauge may be sold at 202, such as to manufacturers and installed in vehicles by the manufacturer, or may be sold as an aftermarket gauge to end-users. The vehicle gauge and output module may be sold together in some examples at 203, and/or the output module may be sold separately from the vehicle gauge at 204. Selling a separate output module as disclosed may allow for the selling of a standard (off-the-shelf) line of programmable gauges at a lower price point than if the output module's hardware and functionality were built into the off-the-shelf gauges. Thus, customers that do not desire the functionality of the output module do not need to incur the expense for such functionality, while customers that do desire such functionality may separately purchase the output module and install it in connection with the off-the-shelf gauges.

Examples of methods 300 of using disclosed output modules are shown in FIG. 11. A programming cable may be connected to a programmable vehicle gauge (e.g., vehicle gauge 100) at 301. In other examples, programmable vehicle gauge 100 may be pre-programmed, or may be programmable without a programming cable. Connecting a programming cable to the gauge may include inserting a connector onto programming pins (e.g., a programming connection 108) of the gauge in some examples. The vehicle gauge may be programmed at 302, such as by using a computer, mobile device, programming device, or other device. In some examples, programming the gauge at 302 may include setting a maximum and/or minimum threshold value, such that the gauge may be programmed to send a signal in the event that a maximum threshold value is exceeded or that a level or measurement falls below a minimum threshold value. In some examples, the vehicle gauge is programmable any number of times, so that the minimum and/or maximum threshold values may be changed and the gauge re-programmed as desired. In this manner, the vehicle gauge can be customized, optimized, and/or tested and changed for different applications.

In methods where a programming cable is connected to the vehicle gauge to program the gauge, the cable may be removed at 303, such as by unplugging a connector from the programming connection of the gauge. In some examples, the programming cable is not removed after programming. An output module according to the present disclosure may be connected to (e.g., mounted to, coupled to, attached to, etc.) the gauge at 304. Connecting the output module to the gauge may include utilizing a direct mounting connection to couple the output module to the vehicle gauge. In some examples, the output module may be connected to the vehicle gauge without modifying or altering the vehicle gauge. The output module may be selectively removable from the gauge in some examples. The output module may, for example, include one or more through-holes formed in a printed circuit board that may be configured to mount onto one or more respective mounting bosses formed on the gauge. In some examples, the mounting bosses are also configured to mount the gauge in place within a vehicle.

The output module may also be connected to an external device at 305. Connecting the output module to an external device may include connecting wires or cables from the external device to a terminal or other connector on the output module. The output module may be connected to an external device at 305 before or after it is mounted on the vehicle gauge at 304. Once connected, the output module may send a switch signal to the external device whenever conditions rise above the maximum threshold value or fall below the minimum threshold value as programmed onto the gauge. Depending on the configuration of the gauge, a relay may switch from being normally open to being closed (or vice versa) in response to a switch signal received from the output gauge. In this manner, the external device may be controlled (either isolated from receiving current and/or voltage, or connected) depending on conditions detected or received by the gauge. In one specific example, a maximum threshold oil pressure may be programmed onto a vehicle gauge. When the measured or detected oil pressure rises above the maximum threshold oil pressure, a switch signal may be sent to the output module such that the relay closes the circuit and an engine kill switch is activated to shut down the vehicle's engine. Many other applications and uses are also possible.

Illustrative, non-exclusive examples of inventive subject matter according to the present disclosure are described in the following enumerated paragraphs.

A1. An output module, comprising:

a printed circuit board containing a plurality of passive circuit elements;

a relay mounted on the printed circuit board; and

a direct mounting connection, wherein the direct mounting connection is configured to removably couple the output module to a gauge.

A2. The output module according to paragraph A1, wherein the output module is configured to send a switch signal to an external device.

A3. The output module according to any of paragraphs A1-A2, wherein the output module is configured to send a switch signal to one or more of a warning light, a kill switch, and an alarm.

A4. The output module according to any of paragraphs A1-A3, wherein the output module has a relatively thin profile.

A5. The output module according to any of paragraphs A1-A4, wherein the printed circuit board comprises an upper surface and a lower surface.

A6. The output module according to paragraph A5, wherein the printed circuit board includes at least one mounting hole extending from the upper surface to the lower surface.

A7. The output module according to paragraph A6, wherein each of the at least one mounting holes includes an elastomeric grommet positioned within each respective mounting hole.

A8. The output module according to any of paragraphs A6-A7, wherein the direct mounting connection comprises the at least one mounting hole.

A9. The output module according to any of paragraphs A6-A8 wherein the direct mounting connection comprises the elastomeric grommet.

A10. The output module according to any of paragraphs A5-A9, wherein the printed circuit board comprises a connector positioned on the lower surface, the connector being configured to connect the output module to one or more pins separate from the output module.

A11. The output module according to any of paragraphs A5-A10, wherein at least a portion of the plurality of passive circuit elements is positioned on the upper surface of the printed circuit board.

A12. The output module according to any of paragraphs A1-A11, wherein the plurality of passive circuit elements includes at least one of: a resistor, a capacitor, and a diode.

A13. The output module according to any of paragraphs A2-A12, wherein the output module comprises a terminal strip, the terminal strip being configured to receive one or more wires configured to send the switch signal to the external device.

A14. The output module according to paragraph A13, wherein the terminal strip is electrically connected to the relay.

A15. The output module according to any of paragraphs A13-A14, wherein the terminal strip is positioned on the upper surface of the printed circuit board.

A16. The output module according to any of paragraphs A5-A14, wherein the relay is positioned on the upper surface of the printed circuit board.

A17. The output module according to any of paragraphs A1-A16, wherein at least a portion of the printed circuit board is shaped to conform to the gauge that the direct mounting connection is configured to removably couple the output module to.

A18. The output module according to any of paragraphs A1-A17, wherein the perimeter of the printed circuit board comprises a straight edge and an arc.

B1. A vehicle gauge, comprising:

a gauge housing including a display opening and a rear face; and

an output module according to any of paragraphs A1-A18, wherein the output module is removably coupled to the rear face of the gauge housing.

B2. The vehicle gauge of paragraph B1 further comprising one or more mounting bosses on the rear face, the mounting bosses being configured to mount the vehicle gauge within a vehicle, wherein the output module is removably coupled to the rear face via the mounting bosses.

B3. The vehicle gauge according to paragraph B2, wherein the printed circuit board of the output module includes at least one through-hole, the at least one through-hole being configured to interface with the one or more mounting bosses on the rear face of the gauge housing.

B4. The vehicle gauge according to paragraph B3, wherein each of the at least one through-holes includes an elastomeric grommet extending through the at least one through-hole.

B5. The vehicle gauge according to paragraph B4, wherein each of the elastomeric grommets is configured to be inserted onto a respective one of the one or more mounting bosses.

B6. The vehicle gauge according to paragraph B5, wherein the elastomeric grommet is configured to engage with the mounting boss via a friction fit.

B7. The vehicle gauge according to any of paragraphs B1-B6, further comprising one or more programming connections positioned on the rear face of the gauge housing, the programming connections being configured to program the vehicle gauge.

B8. The vehicle gauge according to paragraph B7, wherein the programming connections are configured to allow communication between the output module and the vehicle gauge.

B9. The vehicle gauge according to paragraph B8, wherein the output module includes a connector that interfaces with the programming connections of the vehicle gauge.

B10. The vehicle gauge according to any of paragraphs B1-B9, wherein the perimeter of the output module is sized and shaped to be positioned within the perimeter of the gauge housing, such that the output module does not extend circumferentially beyond the gauge housing.

B11. The vehicle gauge according to any of paragraphs B7-B10, wherein the programming connections are accessible while the output module is removably coupled to the rear face of the gauge housing.

C1. A system, comprising:
a vehicle gauge according to any of paragraphs B1-B11; and

an external device that is electrically coupled to the output module and separate from the vehicle gauge, wherein the output module is configured to send a switch signal to the external device in response to a condition detected by the vehicle gauge, wherein the switch signal is configured to cause the external device to perform a function.

C2. The system according to paragraph C1, wherein the external device is at least one of a warning light, an indicator light, a blinking light, a speaker, a buzzer, an alarm, and a kill switch.

D1. A method, comprising:

selling a programmable vehicle gauge, the programmable vehicle gauge comprising a rear face and an opposing gauge display face, wherein the gauge display face is configured to display information measured by the vehicle gauge, the vehicle gauge further comprises at least one mounting boss on the rear face, the at least one mounting boss being configured to mount the vehicle gauge within a vehicle, the programmable vehicle gauge being programmable to send a switch signal when a measured data value rises above and/or falls below a programmed threshold level; and

selling an output module separately from the programmable vehicle gauge, the output module being configured to control an external device in response to receiving the switch signal from the programmable vehicle gauge, wherein the output module is configured to be directly connected to the programmable vehicle gauge.

D2. The method according to paragraph D1, wherein the output module is configured to be directly connected to the rear face of the programmable vehicle gauge.

D3. The method according to any of paragraphs D1-D2, wherein the output module is configured to be directly connected to the at least one mounting boss of the programmable vehicle gauge.

D4. The method according to any of paragraphs D1-D3, wherein the output module comprises at least one mounting hole having an elastomeric grommet positioned therein, and wherein the elastomeric grommet of the output module is configured to be pressed onto the at least one mounting boss of the programmable vehicle gauge such that the at least one mounting boss is inserted at least partially through the elastomeric grommet.

D5. The method according to any of paragraphs D1-D4, further comprising preinstalling software on the programmable vehicle gauge prior to the selling the output module separately from the programmable vehicle gauge, the software being configured to produce a switch signal in response to measured data.

D6. The method according to any of paragraphs D1-D5, wherein the programmable vehicle gauge is the vehicle gauge according to any of paragraphs B1-B11.

D7. The method according to any of paragraphs D1-D6, wherein the output module is the output module according to any of paragraphs A1-A18.

E1. A method, comprising:

connecting a removable programming cable to a vehicle gauge, the vehicle gauge comprising a rear face and an opposing gauge display face, wherein the gauge display face is configured to display information measured by the vehicle gauge, the vehicle gauge further comprises at least one mounting boss on the rear face, the at least one mounting boss being configured to mount the vehicle gauge within a vehicle;

programming the vehicle gauge via the removable programming cable;

removing the removable programming cable from the vehicle gauge; and

directly connecting an output module to the vehicle gauge.

E2. The method according to paragraph E1, wherein the programming the vehicle gauge comprises setting a threshold level for a measured signal.

E3. The method according to any of paragraphs E1-E2, wherein the connecting the removable programming cable to the vehicle gauge comprises inserting a programming cable connector onto a plurality of programming pins.

E4. The method according to paragraph E3, wherein the plurality of programming pins are accessible via the rear face of the vehicle gauge.

E5. The method according to any of paragraphs E1-E4, wherein the directly connecting the output module to the vehicle gauge comprises mounting, plugging, and/or snapping the output module into or onto the rear face of the vehicle gauge.

E6. The method according to any of paragraphs E1-E5, wherein the output module comprises at least one mounting grommet hole comprising a mounting grommet secured within a through-hole formed in the output module, and wherein the directly connecting the output module to the vehicle gauge comprises aligning the at least one mounting grommet hole with a respective at least one mounting boss and pressing the output module towards the rear face of the vehicle gauge such that each of the at least one mounting bosses is inserted at least partially through a respective one of the at least one mounting grommet hole.

E7. The method according to paragraph E6, wherein the directly connecting the output module to the vehicle gauge comprises pressing the output module towards the rear face of the vehicle gauge until the mounting grommet contacts the rear face of the vehicle gauge.

E8. The method according to any of paragraphs E6-E7, wherein the mounting boss has a friction fit within the mounting grommet.

E9. The method according to any of paragraphs E1-E8, wherein the directly connecting the output module to the vehicle gauge comprises pressing an output module connector onto at least one pin of the vehicle gauge.

E10. The method according to any of paragraphs E1-E9, wherein the vehicle gauge comprises a plurality of programming pins and a plurality of control pins.

E11. The method according to paragraph E10, wherein the plurality of programming pins is arranged linearly.

E12. The method according to any of paragraphs E10-E11, wherein the plurality of control pins is arranged linearly.

E13. The method according to any of paragraphs E10-E12, wherein directly connecting the output module to the vehicle gauge comprises pressing an output module connector onto the plurality of control pins.

E14. The method according to any of paragraphs E10-E13, wherein the plurality of programming pins is accessible with the output module directly connected to the vehicle gauge.

E15. The method according to any of paragraphs E1-E14, further comprising controlling an external device in response to a switch signal received from the vehicle gauge.

E16. The method according to any of paragraphs E3-E15, further comprising connecting an external device to the vehicle gauge via the plurality of programming pins.

E17. The method according to any of paragraphs E15-E16, wherein the controlling the external device comprises controlling at least one of a warning light, a buzzer, an alarm, and a kill switch.

E18. The method according to any of paragraphs E2-E17, further comprising configuring the vehicle gauge to receive measured data, and sending a switch signal to the output module if the measured data exceeds the threshold level for the measured signal.

E19. The method according to any of paragraphs E2-E17, further comprising configuring the vehicle gauge to receive measured data, and sending a switch signal to the output module if the measured data falls below the threshold level for the measured signal.

E20. The method according to any of paragraphs E1-E19, wherein the vehicle gauge is the vehicle gauge according to any of paragraphs B1-B11.

E21. The method according to any of paragraphs E1-E20, wherein the output module is the output module according to any of paragraphs A1-A18.

As used herein, the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It is also within the scope of the present disclosure that elements, components, and/or other recited subject matter that is recited as being adapted to perform a particular function may additionally or alternatively be described as being configured to perform that function, and vice versa. Similarly, subject matter that is recited as being configured to perform a particular function may additionally or alternatively be described as being operative to perform that function.

The various disclosed elements of apparatuses and steps of methods disclosed herein are not required to all apparatuses and methods according to the present disclosure, and the present disclosure includes all novel and non-obvious combinations and subcombinations of the various elements and steps disclosed herein. Moreover, one or more of the various elements and steps disclosed herein may define independent inventive subject matter that is separate and apart from the whole of a disclosed apparatus or method. Accordingly, such inventive subject matter is not required to be associated with the specific apparatuses and methods that are expressly disclosed herein, and such inventive subject matter may find utility in apparatuses and/or methods that are not expressly disclosed herein.

1. An output module for use with a vehicle gauge, comprising:
a printed circuit board containing a plurality of passive circuit elements;
a relay mounted on the printed circuit board; and
a direct mounting connection, wherein the direct mounting connection is configured to removably couple the output module to a gauge, and wherein the output module is configured to control an external device via the relay.

2. The output module according to claim 1, wherein the output module is configured to send a switch signal to an external device.

3. The output module according to claim 1, wherein the output module is configured to send a switch signal to one or more of a warning light, a kill switch, and an alarm.

4. The output module according to claim 1, wherein the printed circuit board comprises an upper surface and a lower surface, wherein the printed circuit board includes at least one mounting hole extending from the upper surface to the lower surface, wherein each of the at least one mounting holes includes an elastomeric grommet positioned within each respective mounting hole, and wherein the direct mounting connection comprises the at least one mounting hole and the elastomeric grommet.

5. The output module according to claim 4, wherein the printed circuit board comprises a connector positioned on the lower surface, the connector being configured to connect the output module to one or more pins separate from the output module.

6. The output module according to claim 2, wherein the output module comprises a terminal strip, the terminal strip being configured to receive one or more wires configured to send the switch signal to an external device.

7. The output module according to claim 6, wherein the terminal strip is electrically connected to the relay.

8. A system, comprising:
a vehicle gauge, the vehicle gauge including a gauge housing having a display opening and a rear face arranged on opposing ends of the vehicle gauge;
the output module according to claim 1, wherein the output module is removably coupled to the rear face of the vehicle gauge via the direct mounting connection of the output module and wherein the output module is electrically coupled to the vehicle gauge; and
an external device that is electrically coupled to the output module and separate from the vehicle gauge, wherein the output module is configured to send a switch signal to the external device in response to a condition detected by the vehicle gauge, wherein the switch signal is configured to cause the external device to perform a function.

9. The system according to claim 8, wherein the vehicle gauge comprises one or more mounting bosses on the rear face, the mounting bosses being configured to mount the vehicle gauge within a vehicle, wherein the output module is removably coupled to the rear face via the mounting bosses.

10. The system according to claim 9, wherein the printed circuit board of the output module includes at least one through-hole, the at least one through-hole being configured to interface with the one or more mounting bosses on the rear face of the gauge housing.

11. The system according to claim 10, wherein each of the at least one through-holes includes an elastomeric grommet extending through the at least one through-hole, and wherein each of the elastomeric grommets is configured to be inserted onto a respective one of the one or more mounting bosses, and wherein the elastomeric grommet is configured to engage with the respective mounting boss via a friction fit.

12. The system according to claim 8, wherein the external device is at least one of a warning light, an indicator light, a blinking light, a speaker, a buzzer, an alarm, and a kill switch.

13. The system according to claim 8, wherein at least a portion of the printed circuit board is shaped to conform to the rear face of the vehicle gauge.

14. An output module for use with a vehicle gauge, comprising:
a printed circuit board containing a plurality of passive circuit elements, wherein the printed circuit board comprises an upper surface and a lower surface, wherein the printed circuit board includes at least one mounting hole extending from the upper surface to the lower surface, wherein each of the at least one mounting holes includes an elastomeric grommet positioned within each respective mounting hole, and wherein each of the at least one mounting holes and respective elastomeric grommet is configured to removably couple the output module to a vehicle gauge;
a relay mounted on the printed circuit board;
a connector positioned on the lower surface, the connector being configured to electrically connect the output module to one or more pins separate from the output module; and
a terminal strip, the terminal strip being configured to receive one or more wires configured to send a switch signal to an external device,
wherein the output module is configured to control an external device via the relay.

15. A method, comprising:
connecting a removable programming cable to a vehicle gauge, the vehicle gauge comprising a rear face and an opposing gauge display face, wherein the gauge display face is configured to display information measured by the vehicle gauge, wherein the vehicle gauge further comprises at least one mounting boss on the rear face, the at least one mounting boss being configured to mount the vehicle gauge within a vehicle;
programming the vehicle gauge via the removable programming cable;
removing the removable programming cable from the vehicle gauge; and
directly connecting an output module to the vehicle gauge, wherein the output module is configured to send a switch signal to an external device in response to a condition detected by the vehicle gauge.

16. The method according to claim 15, wherein the programming the vehicle gauge comprises setting a threshold level for a measured signal.

17. The method according to claim 15, wherein the directly connecting the output module to the vehicle gauge comprises directly connecting the output module physically and electrically to the vehicle gauge.

18. The method according claim 15, wherein the output module comprises at least one mounting hole comprising a mounting grommet secured within a through-hole formed in the output module, and wherein the directly connecting the output module to the vehicle gauge comprises aligning the at least one mounting hole with a respective at least one mounting boss and pressing the output module towards the rear face of the vehicle gauge such that each of the at least one mounting bosses is inserted at least partially through a respective one of the at least one mounting hole.
